(19) United States
(12) Patent Application Publication
(10) Pub. No.: US 2025/0240895 A1
(43) Pub. Date: Jul. 24, 2025

(54) METHOD FOR PREPARING METAL MESH AND METHOD FOR PREPARING ANTENNA

(71) Applicant: BOE Technology Group Co., Ltd., Beijing (CN)

(72) Inventors: Yafei ZHANG, Beijing (CN); Dongdong ZHANG, Beijing (CN); Mengwen JIA, Beijing (CN); Xudong ZHANG, Beijing (CN)

(21) Appl. No.: 18/698,175

(22) PCT Filed: Mar. 29, 2023
(86) PCT No.: PCT/CN2023/084559

§ 371 Date: Apr. 3, 2024

(51) Int. Cl. H05K 3/00; H01Q 1/42; H05K 3/18

(52) U.S. Cl. CPC H05K 3/0011; H05K 3/18; H01Q 1/422; H05K 2203/0548; H05K 2203/0723; H05K 2203/095

(57) ABSTRACT

The present disclosure provides a method for preparing a metal mesh and a method for preparing an antenna, and belongs to the technical field of electronic devices. The method for preparing a metal mesh of the present disclosure includes: providing a base substrate; and forming a dielectric layer on the base substrate, and performing dry etching on the dielectric layer by an inductively coupled plasma device to form a meshed groove.

### TECHNICAL FIELD

The present disclosure belongs to the technical field of electronic devices, and specifically relates to a method for preparing a metal mesh and a method for preparing an antenna.

### BACKGROUND

The current micro-nano processing technology commonly used in the glass-based semiconductor industry requires a line width of about 2 μm to 3 μm. Some thin film display or sensing devices, such as transparent antennas or radio frequency devices, put higher requirements on the line width in micro-nano processing. In the transparent antenna, metal meshes of a narrow line width are mainly used as signal transmitting and receiving units, while in the radio frequency device, a narrower channel length is applied to achieve a higher cutoff frequency.

### SUMMARY

To solve at least one of the technical problems in the existing art, the present disclosure provides a method for preparing a metal mesh and a method for preparing an antenna.

In a first aspect, an embodiment of the present disclosure provides a method for preparing a metal mesh, including:
providing a base substrate; and
forming a dielectric layer on the base substrate, and performing dry etching on the dielectric layer by an inductively coupled plasma device to form a meshed groove.

The dielectric layer includes a first dielectric layer and a second dielectric layer stacked together; and the step of forming the dielectric layer on the base substrate, and performing dry etching on the dielectric layer by the inductively coupled plasma device to form the meshed groove includes:
forming the first dielectric layer on the base substrate;
forming the second dielectric layer on a side of the first dielectric layer away from the base substrate;
forming a first photoresist layer on a side of the second dielectric layer away from the first dielectric layer, and exposing and developing the first photoresist layer to form a first mesh pattern;
performing dry etching on the second dielectric layer by the inductively coupled plasma device, to remove exposed material of the second dielectric layer and form a second mesh pattern; taking the second mesh pattern as a mask to perform dry etching on the first dielectric layer by the inductively coupled plasma device, to remove exposed material of the first dielectric layer to form a third mesh pattern, wherein the second mesh pattern and the third mesh pattern are stacked together to form the meshed groove; and
removing a residual part of the first photoresist layer.

The first dielectric layer includes an organic material, and oxygen is used as an etching gas for etching the first dielectric layer.

The organic material includes any one of polyimide, epoxy, acryl, polyester, photoresist, polyacrylate, polyamide, or siloxane.

The first dielectric layer has a thickness of 2 μm to 5 μm.

The second dielectric layer includes an inorganic material, and tetrafluoromethane is used as an etching gas for etching the second dielectric layer.

The inorganic material includes any one of silicon nitride, silicon oxide, or silicon oxynitride.

The second dielectric layer has a thickness of 50 nm to 400 nm.

The step of forming the first dielectric layer on the base substrate includes:
forming a first dielectric material on the base substrate through a coating process, and curing the first dielectric material at a high temperature to form the first dielectric layer.

The step of forming the second dielectric layer on the side of the first dielectric layer away from the base substrate includes:
forming the second dielectric layer on a side of the first dielectric layer away from the base substrate by a plasma chemical vapor deposition device.

The method for preparing a metal mesh further includes: prior to forming the dielectric layer on the base substrate:
forming a first metal film on the base substrate, and taking the first metal film as a seed layer; and
subsequent to forming the meshed groove: removing the second mesh pattern;
electroplating the seed layer to enable growth of the first metal film in the groove; and
removing the dielectric layer and a part of the first metal film on a side of the dielectric layer close to the base substrate, to form a metal mesh.

The first metal film is made of a material including copper or silver.

The method for preparing a metal mesh further includes: subsequent to forming the meshed groove:
removing the second mesh pattern;
forming a first metal film on a side of the meshed groove away from the base substrate, and taking the first metal film as a seed layer; and
electroplating the seed layer to enable growth of the first metal film, and removing a part of the grown first metal film outside the meshed groove to form a metal mesh.

The first metal film is made of a material including copper or silver.

The meshed groove has a width not more than 1.5 μm.

In a second aspect, an embodiment of the present disclosure provides a method for preparing an antenna, including:
providing a first dielectric substrate including a first surface and a second surface opposite to each other in a thickness direction of the first dielectric substrate;
forming a reference electrode layer on the first surface of the first dielectric substrate; and
forming a radiation part on the second surface of the first dielectric substrate; wherein
at least one of the reference electrode layer or the radiation part includes the metal mesh prepared in any of the above methods.

The reference electrode layer and the radiation part are both metal meshes, and orthographic projections of hollowed-out portions of the reference electrode layer and the radiation part on the first dielectric substrate are overlapped.

The first dielectric substrate includes a first dielectric sublayer, a first bonding layer and a second dielectric sublayer stacked together, the reference electrode layer is on a side of the first dielectric sublayer away from the first bonding layer, and the radiation part is on a side of the second dielectric sublayer away from the first bonding layer.

The first dielectric sublayer and/or the second dielectric sublayer are made of a material including polyimide or polyethylene terephthalate.

The first dielectric substrate is a single layer structure made of a material including polyimide or polyethylene terephthalate.

### BRIEF DESCRIPTION OF DRAWINGS

FIG. 1 is a schematic structural diagram of an exemplary thin film sensor.

FIG. 2 is a schematic cross-sectional view of the thin film sensor in FIG. 1 taken along A-A′.

FIG. 3 is a top view of a meshed groove according to an embodiment of the present disclosure.

FIG. 4 is a schematic cross-sectional view of the meshed groove in FIG. 3 taken along B-B′.

FIG. 5 is a flowchart of forming a first example of the meshed groove in a method for preparing a metal mesh according to an embodiment of the present disclosure.

FIG. 6 is a test image of a first example of the meshed groove formed in a method for preparing a metal mesh according to an embodiment of the present disclosure.

FIG. 7 is a test image of a second example of the meshed groove formed in a method for preparing a metal mesh according to an embodiment of the present disclosure.

FIG. 8 is a test image of a third example of the meshed groove formed in a method for preparing a metal mesh according to an embodiment of the present disclosure.

FIG. 9 is a top view of a metal mesh according to an embodiment of the present disclosure.

FIG. 10 is a schematic cross-sectional view of the metal mesh in FIG. 9 taken along C-C′.

FIG. 11 is a preparation flowchart of a first example of a method for preparing a metal mesh according to an embodiment of the present disclosure.

FIG. 12 is a test image of a fourth example of the meshed groove formed in a method for preparing a metal mesh according to an embodiment of the present disclosure.

FIG. 13 is a test image of a fifth example of the meshed groove formed in a method for preparing a metal mesh according to an embodiment of the present disclosure.

FIG. 14 is a test image of a sixth example of the meshed groove formed in a method for preparing a metal mesh according to an embodiment of the present disclosure.

FIG. 15 is a cross-sectional view of an antenna according to an embodiment of the present disclosure.

FIG. 16 is another cross-sectional view of an antenna according to an embodiment of the present disclosure.

### DETAIL DESCRIPTION OF EMBODIMENTS

To improve understanding of the technical solution of the present disclosure for one of ordinary skill in the art, the present disclosure will be described in detail with reference to accompanying drawings and specific implementations.

Unless otherwise defined, technical or scientific terms used in the present disclosure are intended to have general meanings as understood by one of ordinary skill in the art to which the present disclosure belongs. The words “first”, “second” and similar terms used in the present disclosure do not denote any order, quantity, or importance, but are used merely for distinguishing different components from each other. Likewise, the words “a”, “an”, or “the” and similar referents do not denote a limitation of quantity, but rather denote the presence of at least one. The word “comprising” or “including” or the like means that the element or item preceding the word contains elements or items that appear after the word or equivalents thereof, but does not exclude other elements or items. The terms “connected” or “coupled” and the like are not restricted to physical or mechanical connections, but may include electrical connections, whether direct or indirect. The words “upper”, “lower”, “left”, “right”, and the like are merely used to indicate a relative positional relationship, and when an absolute position of the described object is changed, the relative positional relationship may be changed accordingly.

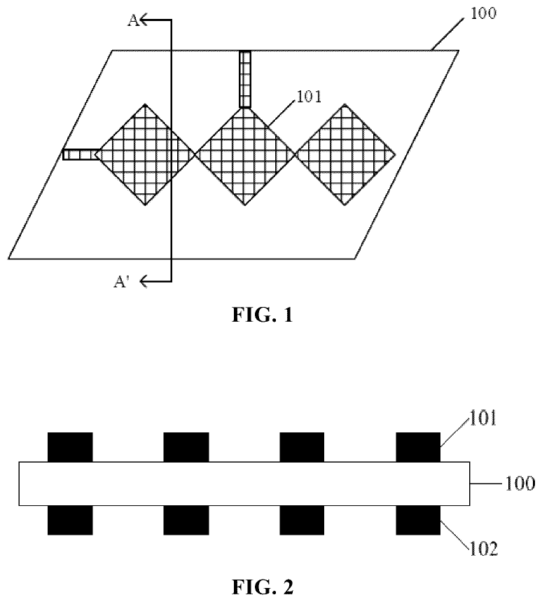

FIG. 1 is a schematic structural diagram of an exemplary thin film sensor; and FIG. 2 is a schematic cross-sectional view of the thin film sensor in FIG. 1 taken along A-A′. As shown in FIGS. 1 and 2, the thin film sensor includes: a base substrate 100 having a first surface and a second surface, i.e., an upper surface and a lower surface, disposed opposite to each other. A first conductive layer 101 and a second conductive layer 102 are located on the first surface and the second surface of the base substrate 100, respectively. Taking the thin film sensor being a transparent antenna as an example, the first conductive layer 101 may be a radiation layer, and the second conductive layer 102 may be a ground layer. The radiation layer can be used as a receiving unit, as well as a transmitting unit, of the antenna structure.

To guarantee good light transmittance of the first conductive layer 101 and the second conductive layer 102, the first conductive layer 101 and the second conductive layer 102 are patterned. For example, the first conductive layer 101 may be formed by metal gridlines, and the second conductive layer 102 may also be formed by metal gridlines. It will be understood that the first conductive layer 101 and the second conductive layer 102 may be formed by structures of other patterns, for example, block electrodes with diamond, triangular, or other patterns, which are not listed here one by one. As can be seen from FIG. 1, the first conductive layer 101 and the second conductive layer 102, i.e., the gridlines, are not provided throughout the two surfaces of the base substrate 100. Any one of the gridlines is formed by metal grids electrically connected together. Due to the material and the forming process of the metal grids, the metal grids have a relatively large line width, which severely affects the light transmittance of the thin film sensor and thus the user experience.

In some examples, to make a metal mesh 501 of a narrower line width, a first dielectric layer 200 and a second dielectric layer 300 may be sequentially formed on the base substrate 100, where the first dielectric layer 200 is used as a buffer layer, and the second dielectric layer 300 is used as a hard mask layer. Then, wet etching is performed to form a meshed groove 201, and then a metal material, i.e., the metal mesh 501, is formed in the groove. However, since the buffer layer and the hard mask layer are made of different materials and have different thicknesses, after the etching process, vertices of the diamond squares in the meshed groove 201 are passivated to different degrees to form rounded corners, and radii of the rounded corners form the etch loss radii. The line width is increased to various degrees at intersections of the meshed groove, thereby affecting the gain of the antenna.

It should be further noted that the metal mesh 501 is not limited to be applied in an antenna structure, and may also be applied in a touch panel as a touch electrode. Apparently, the metal mesh 501 may also be used in a variety of metal lines, which are not listed here one by one.

In a first aspect, in view of the foregoing problems, an embodiment of the present disclosure provides a method for preparing a metal mesh, including: providing a base substrate; and forming a dielectric layer on the base substrate, and performing dry etching on the dielectric layer by an inductively coupled plasma (ICP) device to form a meshed groove. The meshed groove is used for subsequent formation of a metal mesh.

In the embodiment of the present disclosure, dry etching is performed on the dielectric layer by an inductively coupled plasma device, which, compared with wet etching, has better anisotropy and less influence on the etch radius loss, and is beneficial to the subsequent formation of a metal mesh with a narrower line width, thereby reducing the influence on the antenna gain.

In some examples, the base substrate in the embodiments of the present disclosure may be a glass substrate, or may be a flexible film. The flexible film may be made of at least one of COP, polyimide (PI), or polyethylene terephthalate (PET). In the embodiments of the present disclosure, only the base substrate being a glass substrate is taken as an example for illustration.

In some examples, the dielectric layer may include a first dielectric layer and a second dielectric layer. Specifically, the first dielectric layer 200 may be a buffer layer, and the second dielectric layer may be a hard mask layer. Further, the buffer layer includes, but is not limited to, an organic material including, for example, a resin-based material such as polyimide, epoxy, acryl, polyester, photoresist, polyacrylate, polyamide, siloxane, or the like. The hard mask layer includes, but is not limited to, an inorganic material, a metal oxide, a metal material, or the like. The inorganic material includes, for example, silicon nitride (SiNx), silicon oxide (SiO₂), silicon oxynitride (SiON), or the like; the metal material includes, for example, copper (Cu), aluminum (Al), molybdenum (Mo), or silver (Ag); and the metal oxide includes, for example, indium tin oxide (ITO) or the like. In the embodiments of the present disclosure, the hard mask layer made of an inorganic material is taken as an example for illustration.

The step of forming the meshed groove 201 in a case where the buffer layer and the hard mask layer are made of different materials and have different thicknesses will be described in detail below.

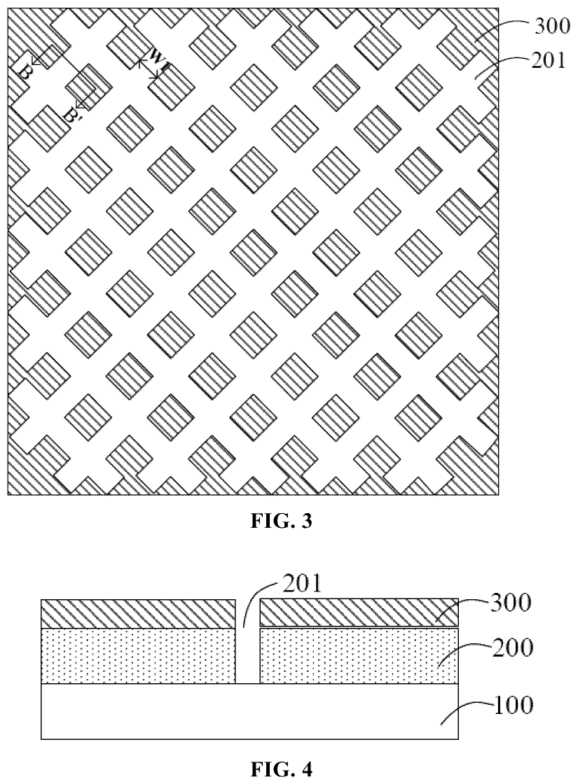

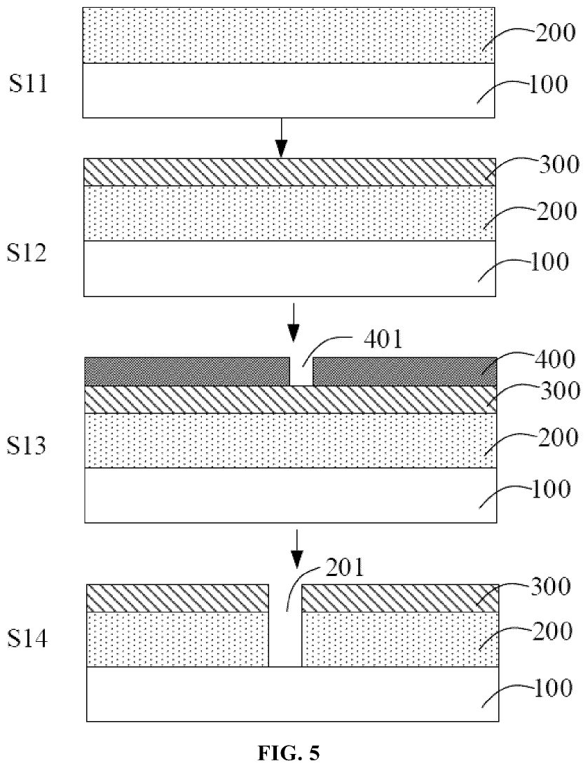

FIG. 3 is a top view of a meshed groove according to an embodiment of the present disclosure; FIG. 4 is a schematic cross-sectional view of the meshed groove in FIG. 3 taken along B-B′; and FIG. 5 is a flowchart of forming a first example of the meshed groove in a method for preparing a metal mesh according to an embodiment of the present disclosure. As shown in FIGS. 3 to 5, the first example includes the following steps S11 to S14. At S11, forming a buffer layer by coating an epoxy resin having a thickness of 4 μm on the base substrate 100, and curing the buffer layer at a high temperature.

At S12, on a side of the buffer layer away from the base substrate 100, forming a hard mask layer by depositing silicon nitride with a thickness of about 200 nm by a plasma enhanced chemical vapor deposition (PECVD) device at a high temperature.

At S13, on a side of the hard mask layer away from the buffer layer, coating, exposing and developing a first photoresist layer 400 (BFP100) to form a first mesh pattern 401.

At S14, performing dry etching on the hard mask layer by an inductively coupled plasma device, to remove exposed material of the hard mask layer to form a second mesh pattern; and taking the second mesh pattern as a mask to perform dry etching on the buffer layer by the inductively coupled plasma device, to remove exposed material of the buffer layer to form a third mesh pattern 2011, and removing a residual part of the first photoresist layer 400 so that the second mesh pattern and the third mesh pattern 2011 are stacked together to form a meshed groove 201.

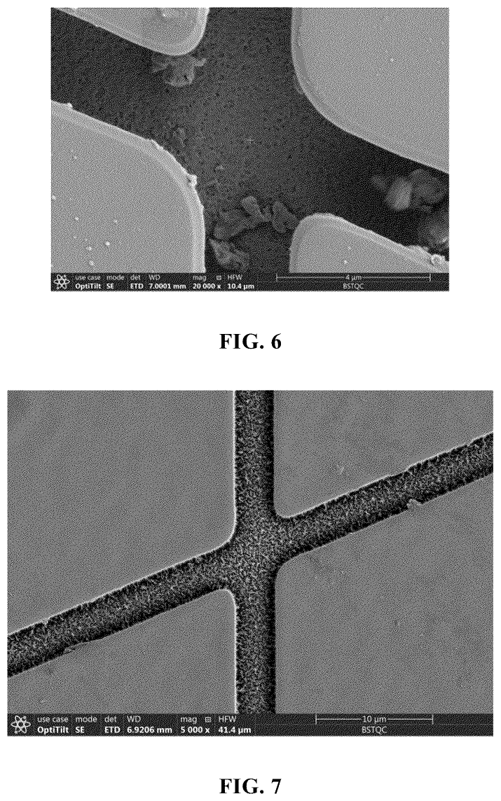

The etching gas used in the dry etching of the hard mask layer in the inductively coupled plasma device is tetrafluoromethane (CF₄), which may slightly etch the first photoresist layer 400 while etching the exposed material of the hard mask layer. Then, the etching gas for etching the buffer layer is oxygen (O₂), which may etch the first photoresist layer 400 while etching the buffer layer. Since the dry etching performed by the inductively coupled plasma device has better anisotropy than wet etching, influence on the etching radius loss is less. FIG. 6 is a test image of a first example of the meshed groove formed in a method for preparing a metal mesh according to an embodiment of the present disclosure. As shown in FIG. 6, after testing, the first example finally forms an etch loss radius of about 0.77 μm, which satisfies the process requirement of being less than 1.5 μm.

Second example: the second example has the same process as the first example, except that the thickness of the buffer layer, and the material of the hard mask layer are different from those in the first example. The second example specifically includes the following steps S21 to S24.

At S21, forming a buffer layer by coating an epoxy resin having a thickness of 3.3 μm on the base substrate 100, and curing the buffer layer at a high temperature.

At S22, on a side of the buffer layer away from the base substrate 100, forming a hard mask layer by depositing silicon oxide with a thickness of about 300 nm by a plasma enhanced chemical vapor deposition (PECVD) device at a high temperature.

At S23, on a side of the hard mask layer away from the buffer layer, coating, exposing and developing a first photoresist layer 400 (BFP100) to form a first mesh pattern 401.

At S24, performing dry etching on the hard mask layer by an inductively coupled plasma device, to remove exposed material of the hard mask layer to form a second mesh pattern; and taking the second mesh pattern as a mask to perform dry etching on the buffer layer by the inductively coupled plasma device, to remove exposed material of the buffer layer to form a third mesh pattern 2011, and removing a residual part of the first photoresist layer 400 so that the second mesh pattern and the third mesh pattern 2011 are stacked together to form a meshed groove 201.

The etching gas used in the dry etching of the hard mask layer in the inductively coupled plasma device is tetrafluoromethane (CF₄), which may slightly etch the first photoresist layer 400 while etching the exposed material of the hard mask layer. Then, the etching gas for etching the buffer layer is oxygen (O₂), which may etch the first photoresist layer 400 while etching the buffer layer. Since the dry etching performed by the inductively coupled plasma device has better anisotropy than wet etching, influence on the etching radius loss is less. FIG. 7 is a test image of a second example of the meshed groove formed in a method for preparing a metal mesh according to an embodiment of the present disclosure. As shown in FIG. 7, after testing, the second example finally forms an etch loss radius of about 1.18 μm, which satisfies the process requirement of being less than 1.5 μm.

Third example: the third example has the same process as the first example, except that the thickness of the buffer layer, and the material of the hard mask layer are different from those in the first example. The third example specifically includes the following steps S31 to S34.

At S31, forming a buffer layer by coating an epoxy resin having a thickness of 5.5 μm on the base substrate 100, and curing the buffer layer at a high temperature.

At S32, on a side of the buffer layer away from the base substrate 100, forming a hard mask layer by depositing silicon oxynitride (a mixture of silicon oxide and silicon nitride) with a thickness of about 200 nm by a plasma enhanced chemical vapor deposition (PECVD) device at a high temperature.

At S33, on a side of the hard mask layer away from the buffer layer, coating, exposing and developing a first photoresist layer 400 (BFP100) to form a first mesh pattern 401.

At S34, performing dry etching on the hard mask layer by an inductively coupled plasma device, to remove exposed material of the hard mask layer to form a second mesh pattern; and taking the second mesh pattern as a mask to perform dry etching on the buffer layer by the inductively coupled plasma device, to remove exposed material of the buffer layer to form a third mesh pattern 2011, and removing a residual part of the first photoresist layer 400 so that the second mesh pattern and the third mesh pattern 2011 are stacked together to form a meshed groove 201.

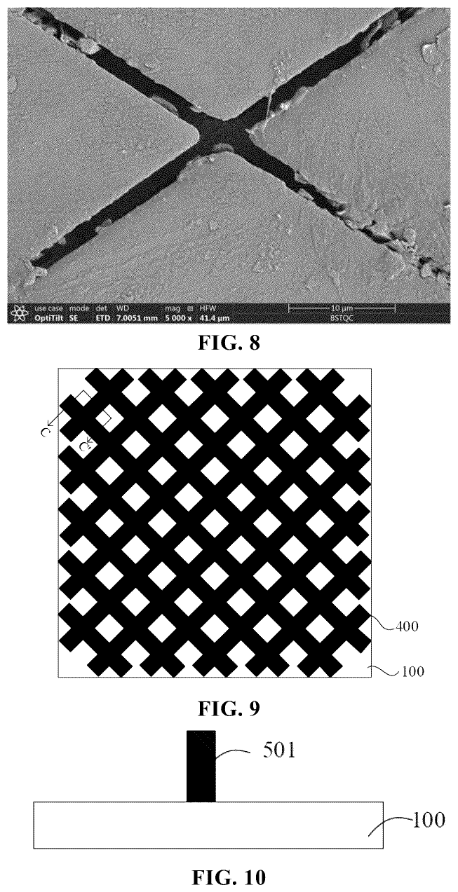

The etching gas used in the dry etching of the hard mask layer in the inductively coupled plasma device is tetrafluoromethane (CF₄), which may slightly etch the first photoresist layer 400 while etching the exposed material of the hard mask layer. Then, the etching gas for etching the buffer layer is oxygen (O₂), which may etch the first photoresist layer 400 while etching the buffer layer. Since the dry etching performed by the inductively coupled plasma device has better anisotropy than wet etching, influence on the etching radius loss is less. FIG. 8 is a test image of a third example of the meshed groove formed in a method for preparing a metal mesh according to an embodiment of the present disclosure. As shown in FIG. 8, after testing, the third example finally forms an etch loss radius of about 0.76 μm, which satisfies the process requirement of being less than 1.5 μm.

In some examples, the method for preparing a thin film sensor according to the embodiment of the present disclosure includes not only a step of forming a meshed groove 201 on the base substrate 100, but also a step of forming a metal mesh 501. A material of the metal mesh 501 includes, but is not limited to, copper, silver, or the like. The following is illustrated with specific examples.

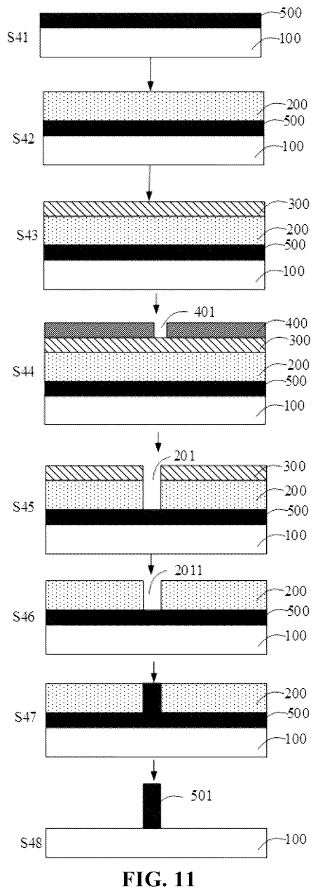

Fourth example: FIG. 9 is a top view of a metal mesh according to an embodiment of the present disclosure. FIG. 10 is a schematic cross-sectional view of the metal mesh in FIG. 9 taken along C-C′. FIG. 11 is a preparation flowchart of a first example of a method for preparing a metal mesh according to an embodiment of the present disclosure. As shown in FIGS. 9 to 11, the preparation method in the fourth example includes the following steps S41 to S48. At S41, forming a first metal film 500 on the base substrate 100. The process used for forming the first metal film 500 includes, but is not limited to, magnetron sputtering. The first metal film 500 is made of copper, and has a thickness of 300 nm.

At S42, on a side of the first metal film away from the base substrate 100, forming a buffer layer by coating an epoxy resin having a thickness of 4.9 μm, and curing the buffer layer at a high temperature.

At S43, on a side of the buffer layer away from the base substrate 100, forming a hard mask layer by depositing silicon nitride with a thickness of about 300 nm by a plasma enhanced chemical vapor deposition (PECVD) device at a high temperature.

At S44, on a side of the hard mask layer away from the buffer layer, coating, exposing and developing a first photoresist layer 400 (BFP100) to form a first mesh pattern 401.

At S45, performing dry etching on the hard mask layer by an inductively coupled plasma device, to remove exposed material of the hard mask layer to form a second mesh pattern; and taking the second mesh pattern as a mask to perform dry etching on the buffer layer by the inductively coupled plasma device, to remove exposed material of the buffer layer to form a third mesh pattern 2011, and removing a residual part of the first photoresist layer 400 so that the second mesh pattern and the third mesh pattern 2011 are stacked together to form a meshed groove 201.

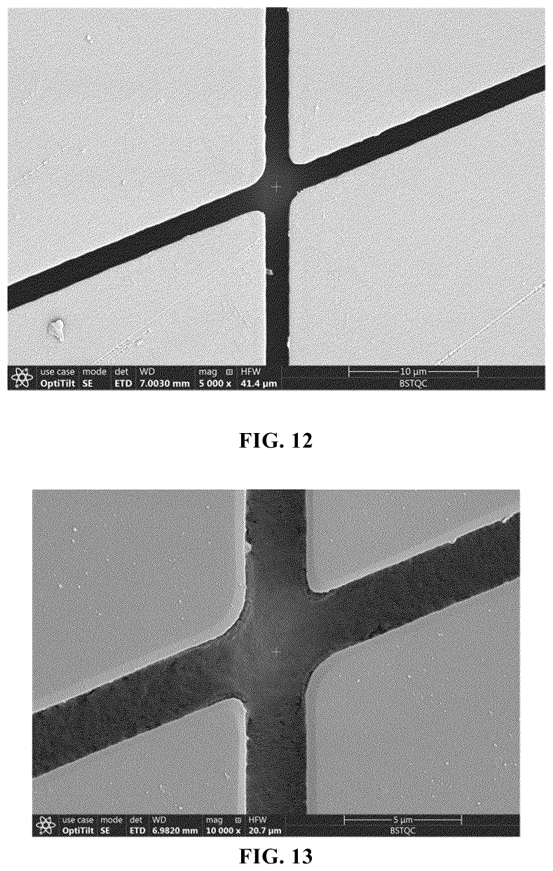

The etching gas used in the dry etching of the hard mask layer in the inductively coupled plasma device is tetrafluoromethane (CF₄), which may slightly etch the first photoresist layer 400 while etching the exposed material of the hard mask layer. Then, the etching gas for etching the buffer layer is oxygen (O₂), which may etch the first photoresist layer 400 while etching the buffer layer. Since the dry etching performed by the inductively coupled plasma device has better anisotropy than wet etching, influence on the etching radius loss is less. FIG. 12 is a test image of a fourth example of the meshed groove formed in a method for preparing a metal mesh according to an embodiment of the present disclosure. As shown in FIG. 12, after testing, the fourth example finally forms an etch loss radius of about 0.82 μm, which satisfies the process requirement of being less than 1.5 μm. However, it should be noted that the buffer layer should not be etched by oxygen for a long time, otherwise not only etch radius loss, but also oxidation of the seed layer, may be caused.

At S46, removing the second mesh pattern.

At S47, taking the first metal film layer as a seed layer for electroplating.

In some examples, the step S47 specifically includes placing a side of the base substrate 100 with the meshed groove 201 on an electroplating machine carrier, pressing a power-on pad, placing the base substrate 100 into a hole-filling electroplating bath (using a dedicated hole-filling electrolyte), and applying a current, where the electroplating solution keeps flowing continuously and rapidly on a surface of the base substrate 100, so that on sidewalls of the groove, cations in the electroplating solution acquire electrons to form atoms deposited on the sidewalls. By means of a specially formulated dedicated hole-filling electrolyte, it is possible to deposit metallic copper at a high speed (at a deposition rate of 0.5 to 3 μm/min) mainly in the groove. As time goes by, the metallic copper on the sidewalls of the groove gradually grows thick, and can even fill up the groove. Finally, the base substrate 100 is taken out and washed by deionized water.

At S48, removing a material of the first metal film layer on the base substrate 100 except the metal material in the groove, to form a metal mesh 501.

Fifth example: the fifth example has the same process as the fourth example, except that the thickness of the buffer layer, and the material of the hard mask layer are different from those in the fourth example. The fifth example specifically includes the following steps S51 to S58.

At S51, forming a first metal film 500 on the base substrate 100. The process used for forming the first metal film 500 includes, but is not limited to, magnetron sputtering. The first metal film 500 is made of copper, and has a thickness of 300 nm.

At S52, on a side of the first metal film away from the base substrate 100, forming a buffer layer by coating an epoxy resin having a thickness of 3.3 μm, and curing the buffer layer at a high temperature.

At S53, on a side of the buffer layer away from the base substrate 100, forming a hard mask layer by depositing silicon oxynitride (a mixture of silicon nitride and silicon oxide) with a thickness of about 100 nm by a plasma enhanced chemical vapor deposition (PECVD) device at a high temperature.

At S54, on a side of the hard mask layer away from the buffer layer, coating, exposing and developing a first photoresist layer 400 (BFP100) to form a first mesh pattern 401.

At S55, performing dry etching on the hard mask layer by an inductively coupled plasma device, to remove exposed material of the hard mask layer to form a second mesh pattern; and taking the second mesh pattern as a mask to perform dry etching on the buffer layer by the inductively coupled plasma device, to remove exposed material of the buffer layer to form a third mesh pattern 2011, and removing a residual part of the first photoresist layer 400 so that the second mesh pattern and the third mesh pattern 2011 are stacked together to form a meshed groove 201.

The etching gas used in the dry etching of the hard mask layer in the inductively coupled plasma device is tetrafluoromethane (CF₄), which may slightly etch the first photoresist layer 400 while etching the exposed material of the hard mask layer. Then, the etching gas for etching the buffer layer is oxygen (O₂), which may etch the first photoresist layer 400 while etching the buffer layer. Since the dry etching performed by the inductively coupled plasma device has better anisotropy than wet etching, influence on the etching radius loss is less. FIG. 13 is a test image of a fifth example of the meshed groove formed in a method for preparing a metal mesh according to an embodiment of the present disclosure. As shown in FIG. 13, after testing, the fifth example finally forms an etch loss radius of about 0.60 μm, which satisfies the process requirement of being less than 1.5 μm. However, it should be noted that the buffer layer should not be etched by oxygen for a long time, otherwise not only etch radius loss, but also oxidation of the seed layer, may be caused.

At S56, removing the second mesh pattern.

At S57, taking the first metal film layer as a seed layer for electroplating.

In some examples, the step S57 specifically includes placing a side of the base substrate 100 with the meshed groove 201 on an electroplating machine carrier, pressing a power-on pad, placing the base substrate 100 into a hole-filling electroplating bath (using a dedicated hole-filling electrolyte), and applying a current, where the electroplating solution keeps flowing continuously and rapidly on a surface of the base substrate 100, so that on sidewalls of the groove, cations in the electroplating solution acquire electrons to form atoms deposited on the sidewalls. By means of a specially formulated dedicated hole-filling electrolyte, it is possible to deposit metallic copper at a high speed (at a deposition rate of 0.5 to 3 μm/min) mainly in the groove. As time goes by, the metallic copper on the sidewalls of the groove gradually grows thick, and can even fill up the groove. Finally, the base substrate 100 is taken out and washed by deionized water.

At S58, removing a material of the first metal film layer on the base substrate 100 except the metal material in the groove, to form a metal mesh 501.

Sixth example: the sixth example has the same process as the fourth example, except that the thickness of the buffer layer, and the material of the hard mask layer are different from those of the fourth example. The sixth example specifically includes the following steps S61 to S68.

At S61, forming a first metal film 500 on the base substrate 100. The process used for forming the first metal film 500 includes, but is not limited to, magnetron sputtering. The first metal film 500 is made of silver, and has a thickness of 300 nm.

At S62, on a side of the first metal film away from the base substrate 100, forming a buffer layer by coating an epoxy resin having a thickness of 3.3 μm, and curing the buffer layer at a high temperature.

At S63, on a side of the buffer layer away from the base substrate 100, forming a hard mask layer by depositing silicon oxynitride (a mixture of silicon nitride and silicon oxide) with a thickness of about 100 nm by a plasma enhanced chemical vapor deposition (PECVD) device at a high temperature.

At S64, on a side of the hard mask layer away from the buffer layer, coating, exposing and developing a first photoresist layer 400 (BFP100) to form a first mesh pattern 401.

At S65, performing dry etching on the hard mask layer by an inductively coupled plasma device, to remove exposed material of the hard mask layer to form a second mesh pattern; and taking the second mesh pattern as a mask to perform dry etching on the buffer layer by the inductively coupled plasma device, to remove exposed material of the buffer layer to form a third mesh pattern 2011, and removing a residual part of the first photoresist layer 400 so that the second mesh pattern and the third mesh pattern 2011 are stacked together to form a meshed groove 201.

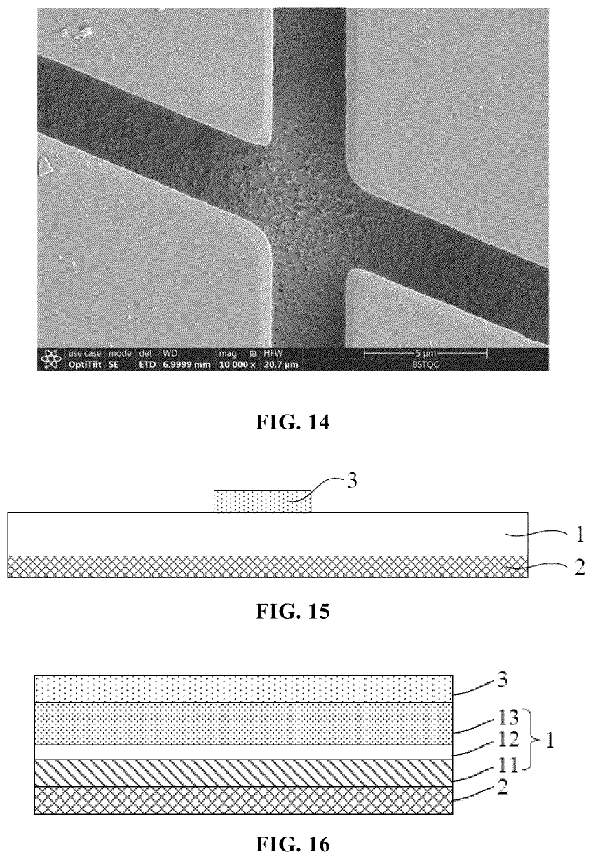

The etching gas used in the dry etching of the hard mask layer in the inductively coupled plasma device is tetrafluoromethane (CF₄), which may slightly etch the first photoresist layer 400 while etching the exposed material of the hard mask layer. Then, the etching gas for etching the buffer layer is oxygen (O₂), which may etch the first photoresist layer 400 while etching the buffer layer. Since the dry etching performed by the inductively coupled plasma device has better anisotropy than wet etching, influence on the etching radius loss is less. FIG. 14 is a test image of a sixth example of the meshed groove in a thin film sensor according to an embodiment of the present disclosure. As shown in FIG. 14, after testing, the sixth example finally forms an etch loss radius of about 0.68 μm, which satisfies the process requirement of being less than 1.5 μm. However, it should be noted that the buffer layer should not be etched by oxygen for a long time, otherwise not only etch radius loss, but also oxidation of the seed layer, may be caused.

At S66, removing the second mesh pattern.

At S67, taking the first metal film layer as a seed layer for electroplating.

In some examples, the step S67 specifically includes placing a side of the base substrate 100 with the meshed groove 201 on an electroplating machine carrier, pressing a power-on pad, placing the base substrate 100 into a hole-filling electroplating bath (using a dedicated hole-filling electrolyte), and applying a current, where the electroplating solution keeps flowing continuously and rapidly on a surface of the base substrate 100, so that on sidewalls of the groove, cations in the electroplating solution acquire electrons to form atoms deposited on the sidewalls. By means of a specially formulated dedicated hole-filling electrolyte, it is possible to deposit metallic copper at a high speed (at a deposition rate of 0.5 to 3 μm/min) mainly in the groove. As time goes by, the metallic copper on the sidewalls of the groove gradually grows thick, and can even fill up the groove. Finally, the base substrate 100 is taken out and washed by deionized water.

At S68, removing a material of the first metal film layer on the base substrate 100 except the metal material in the groove, to form a metal mesh 501.

Apparently, in some examples, the first metal film 500 as the seed layer may be formed after the meshed groove 201 is formed, and then electroplating is performed, so as to grow the metal material in the groove, and finally, a part of the first metal film 500 except the metal material in the groove is removed to form the metal mesh 501.

In a second aspect, FIG. 15 is a cross-sectional view of an antenna according to an embodiment of the present disclosure. As shown in FIG. 15, an embodiment of the present disclosure provides a method for preparing an antenna, including: providing a first dielectric substrate including a first surface and a second surface disposed opposite to each other in a thickness direction of the first dielectric substrate; forming a reference electrode layer on the first surface of the first dielectric substrate; and forming a radiation part on the second surface of the first dielectric substrate. At least one of the reference electrode layer or the radiation part is a metal mesh that may be prepared in any of the above methods.

If the reference electrode layer and the radiation part both adopt a metal mesh structure, the formed antenna is a transparent antenna. The transparent antenna may be applied in glazing systems including, but not limited to, those for automobiles, trains (including high-speed trains), aircrafts, buildings, and the like. The transparent antenna may be fixed to an inner side of the glazing (a side close to the room). Since the transparent antenna has high optical transmittance, it has little influence on the transmittance of the glazing while enabling a communication function, and the transparent antenna also represents a trend of beautified antennas. The glazing in the embodiments of the present disclosure includes, but is not limited to, double-glazing, and types of the glazing may further include single glazing, laminated glazing, thin glazing, thick glazing, and the like.

In the embodiments of the present disclosure, the reference electrode layer and the radiation part both adopt a metal mesh structure, and orthographic projections of hollowed-out portions of metal meshes of the two on the first dielectric substrate are overlapped, so as to increase the light transmittance. Extending directions of first metal lines and second metal lines of the metal mesh may be perpendicular to each other, and in this case, square or rectangular hollowed-out portions are formed. Apparently, the extending directions of the first metal lines and the second metal lines of the metal mesh may be not perpendicular to each other. For example: the extending directions of the first metal lines and the second metal lines form an angle of 45°, and in this case, diamond hollowed-out portions are formed.

In some examples, the first dielectric substrate may be the base substrate as described above, or may be a separately provided dielectric substrate. The first dielectric substrate in the embodiment of the present disclosure may have a single-layer structure, and made of a material including polyimide or polyethylene terephthalate. FIG. 16 is another cross-sectional view of an antenna according to an embodiment of the present disclosure. As shown in FIG. 16, The first dielectric substrate in the embodiment of the present disclosure includes a first dielectric sublayer, a first bonding layer, a second dielectric sublayer, a second bonding layer, and a third dielectric sublayer sequentially stacked together. The reference electrode layer is provided on a side of the first dielectric sublayer close to the first bonding layer; and the radiation part is provided on a side of the second dielectric sublayer close to the second bonding layer. The first dielectric sublayer may be made of polyimide or polyethylene terephthalate, and the second dielectric sublayer may be also made of polyimide or polyethylene terephthalate. The first bonding layer may be made of an optical clear adhesive.

Apparently, the method for preparing an antenna according to the embodiment of the present disclosure may further include steps of forming other structures such as a feed network, which are not listed here one by one.

It will be appreciated that the above implementations are merely exemplary implementations for the purpose of illustrating the principle of the present disclosure, and the present disclosure is not limited thereto. It will be apparent to one of ordinary skill in the art that various modifications and variations may be made without departing from the spirit or essence of the present disclosure. Such modifications and variations should also be considered as falling into the protection scope of the present disclosure.

1. A method for preparing a metal mesh, comprising:
providing a base substrate; and
forming a dielectric layer on the base substrate, and performing dry etching on the dielectric layer by an inductively coupled plasma device to form a meshed groove.

2. The method according to claim 1, wherein the dielectric layer comprises a first dielectric layer and a second dielectric layer stacked together; and the step of forming the dielectric layer on the base substrate, and performing dry etching on the dielectric layer by the inductively coupled plasma device to form the meshed groove comprises:
forming the first dielectric layer on the base substrate;
forming the second dielectric layer on a side of the first dielectric layer away from the base substrate;
forming a first photoresist layer on a side of the second dielectric layer away from the first dielectric layer, and exposing and developing the first photoresist layer to form a first mesh pattern;
performing dry etching on the second dielectric layer by the inductively coupled plasma device, to remove exposed material of the second dielectric layer and form a second mesh pattern; taking the second mesh pattern as a mask to perform dry etching on the first dielectric layer by the inductively coupled plasma device, to remove exposed material of the first dielectric layer to form a third mesh pattern, wherein the second mesh pattern and the third mesh pattern are stacked together to form the meshed groove; and
removing a residual part of the first photoresist layer.

3. The method according to claim 2, wherein the first dielectric layer comprises an organic material, and oxygen is used as an etching gas for etching the first dielectric layer.

4. The method according to claim 3, wherein the organic material comprises any one of polyimide, epoxy, acryl, polyester, photoresist, polyacrylate, polyamide, or siloxane.

5. The method according to claim 2, wherein the first dielectric layer has a thickness of 2 μm to 5 μm.

6. The method according to claim 2, wherein the second dielectric layer comprises an inorganic material; and tetrafluoromethane is used as an etching gas for etching the second dielectric layer.

7. The method according to claim 6, wherein the inorganic material comprises any one of silicon nitride, silicon oxide, or silicon oxynitride.

8. The method according to claim 2, wherein the second dielectric layer has a thickness of 50 nm to 400 nm.

9. The method according to claim 2, wherein the step of forming the first dielectric layer on the base substrate comprises:
forming a first dielectric material on the base substrate through a coating process, and curing the first dielectric material at a high temperature to form the first dielectric layer.

10. The method according to claim 2, wherein the step of forming the second dielectric layer on the side of the first dielectric layer away from the base substrate comprises:
forming the second dielectric layer on a side of the first dielectric layer away from the base substrate by a plasma chemical vapor deposition device.

11. The method according to claim 2, wherein prior to forming the dielectric layer on the base substrate, the method further comprises:
forming a first metal film on the base substrate, and taking the first metal film as a seed layer; and
subsequent to forming the meshed groove, the method further comprises: removing the second mesh pattern;
electroplating the seed layer to enable growth of the first metal film in the groove; and
removing the dielectric layer and a part the first metal film on a side of the dielectric layer close to the base substrate, to form a metal mesh.

12. The method according to claim 11, wherein the first metal film is made of a material comprising copper or silver.

13. The method according to claim 2, wherein subsequent to forming the meshed groove, the method further comprises:
removing the second mesh pattern;
forming a first metal film on a side of the meshed groove away from the base substrate, and taking the first metal film as a seed layer; and
electroplating the seed layer to enable growth of the first metal film, and removing a part of the grown first metal film outside the meshed groove to form a metal mesh.

14. The method according to claim 13, wherein the first metal film is made of a material comprising copper or silver.

15. The method according to claim 1, wherein the meshed groove has a width not more than 1.5 μm.

16. A method for preparing an antenna, comprising:
providing a first dielectric substrate comprising a first surface and a second surface opposite to each other in a thickness direction of the first dielectric substrate;
forming a reference electrode layer on the first surface of the first dielectric substrate; and
forming a radiation part on the second surface of the first dielectric substrate;
wherein at least one of the reference electrode layer or the radiation part comprises the metal mesh prepared by the method according to claim 1.

17. The method according to claim 16, wherein the reference electrode layer and the radiation part are both metal meshes, and orthographic projections of hollowed-out portions of the reference electrode layer and the radiation part on the first dielectric substrate are overlapped.

18. The method according to claim 16, wherein the first dielectric substrate comprises a first dielectric sublayer, a first bonding layer and a second dielectric sublayer stacked together, the reference electrode layer is on a side of the first dielectric sublayer away from the first bonding layer, and the radiation part is on a side of the second dielectric sublayer away from the first bonding layer.

19. The method according to claim 18, wherein the first dielectric sublayer and/or the second dielectric sublayer are made of a material comprising polyimide or polyethylene terephthalate.

20. The method according to claim 16, wherein the first dielectric substrate is a single layer structure made of a material comprising polyimide or polyethylene terephthalate.
